(19) United States
(12) Patent Application Publication
(10) Pub. No.: US 2013/0093059 A1
(43) Pub. Date: Apr. 18, 2013

(54) Bonded Substrate And Method Of Manufacturing The Same

(71) Applicant: Samsung Corning Precision Materials, Co., Ltd., Gyeongsangbuk-do (KR)

(72) Inventors: JongPil Jeon, ChungCheongNam-Do (KR); Dong-Woon Kim, ChungCheongNam-Do (KR); Donghyun Kim, ChungCheongNam-Do (KR); MinJu Kim, ChungCheongNam-Do (KR); A-Ra Kim, ChungCheongNam-Do (KR); Joong Won Shur, ChungCheongNam-Do (KR); Kyungsub Jung, ChungCheongNam-Do (KR); BongHee Jang, ChungCheongNam-Do (KR)

(73) Assignee: SAMSUNG CORNING PRECISION MATERIALS CO., LTD., Gyeongsangbuk-do (KR)

(21) Appl. No.: 13/649,732

(22) Filed: Oct. 11, 2012

(30) Foreign Application Priority Data
Oct. 14, 2011 (KR) 10-2011-0105374

(51) Int. Cl. H01L 21/762; H01L 29/20

(52) U.S. Cl. 257/615; 438/458; 257/E29.089; 257/E21.568

(57) ABSTRACT

A bonded substrate, the surface roughness of which is reduced, and a method of manufacturing the same. The bonded substrate includes a base substrate and an intermediate layer disposed on the base substrate. The intermediate layer has a greater bubble diffusivity than the base substrate. A thin film layer is bonded onto the intermediate layer, and has a different chemical composition from the base substrate.

### CROSS REFERENCE TO RELATED APPLICATION

The present application claims priority from Korean Patent Application Number 10-2011-0105374 filed on Oct. 14, 2011, the entire contents of which application are incorporated herein for all purposes by this reference.

### BACKGROUND OF THE INVENTION

1. Field of the Invention

The present invention relates to a bonded substrate and a method of manufacturing the same, and more particularly, to a bonded substrate, the surface roughness of which is reduced, and a method of manufacturing the same.

2. Description of Related Art

The performance and lifespan of a semiconductor device, such as a laser diode or a light-emitting diode (LED), are determined by a variety of components that constitute the corresponding device, in particular, by a base substrate on which devices are stacked. Accordingly, while several methods for manufacturing high-quality semiconductor substrates are being proposed, interest in group III-V compound semiconductor substrates is increasing.

Here, gallium nitride (GaN) substrates can be regarded as a representative example of group III-V compound semiconductor substrates. While GaN substrates are suitable for semiconductor devices together with gallium arsenide (GaAs) substrates, indium phosphide (InP) substrates, and the like, the manufacturing cost thereof is much more expensive than those of GaAs substrates and InP substrates. Accordingly, the manufacturing cost of semiconductor devices which adopt GaN substrates becomes very high. The manufacturing cost of GaN substrates is high for the following reasons.

Specifically, as for GaAs substrates and InP substrates, the growth rate of crystal is rapid since crystalline growth is carried out by a liquid method, such as the Bridgman method or the Czochralski method. It is therefore possible to easily produce a large GaAs or InP crystalline bulk having a thickness of 200 nm or greater in a crystal growth time of, for example, about 100 hours. Accordingly, a large number of, for example, 100 or more GaAs or InP substrates having a thickness ranging from 200 μm to 400 μm can be divided from the large GaAs or InP crystalline bulk.

In contrast, as for GaN substrates, the growth rate of crystal is slow since crystalline growth is carried out by a vapor deposition method, such as hydride vapor phase epitaxy (HVPE) or metal organic chemical vapor deposition (MOCVD). For example, a GaN crystalline bulk can be produced with a thickness of only about 10 mm for a crystal growth time of 100 hours. When the thickness of the crystal is in that range, only a small number of, for example, 10 GaN substrates having a thickness ranging from 200 μm to 400 μm can be divided from that crystal.

However, when the thickness of a GaN film to be divided from the GaN crystalline bulk is reduced in order to increase the number of divided GaN substrates, the mechanical strength of the divided substrates decreases to the extent that the divided substrates cannot make a self-supporting substrate. Therefore, a method for reinforcing the strength of a GaN thin film layer that is divided from the GaN crystalline bulk was required.

As the method for reinforcing a GaN thin film layer of the related art, there is a method of manufacturing a substrate (hereinafter, referred to as a bonded substrate) in which a GaN thin film layer is bonded to a heterogeneous substrate which has a different chemical composition from GaN, for example, a Si substrate. However, the bonded substrate which is manufactured by the method of manufacturing a bonded substrate of the related art has a problem in that the GaN thin film layer easily peels off the heterogeneous substrate during the process of stacking a semiconductor layer on the GaN thin film layer.

In order to overcome this problem, a method for dividing a thin film layer via ion implantation was proposed. This method manufactures a bonded substrate in which a GaN thin film layer is bonded to a heterogeneous substrate by forming an ion implantation layer, i.e. a damage layer, by irradiating one surface of a GaN crystalline bulk which is supposed to be bonded to the heterogeneous substrate with hydrogen, helium or nitrogen ions; directly bonding the GaN crystalline bulk in which the damage layer is formed to the heterogeneous substrate; heat-treating the resultant structure; and then dividing the GaN crystalline bulk on the damage layer.

However, in the related art, bubbles are formed owing to residues occurring from cleaning and surface treatment processes on a bonding interface while the heterogeneous substrates are bonded together, and are present in the shape of voids. In addition, the bubbles expand and swell while undergoing subsequent heat treatment at a high temperature, thereby functioning as a reason that worsens the surface roughness and bonding state of a GaN transferred layer, i.e. a GaN thin film layer. That is, a number of voids formed in the bonding interface are distributed significantly in the circular shape over the entire area of the GaN transferred layer. The voids are swollen and expanded through heat treatment, and are present as being trapped in the bonding interface. Owing to such voids, circular protrusions corresponding to the volume of the voids are formed on the surface of the GaN thin film layer. Furthermore, the surface of the GaN thin film layer which is roughened by the circular protrusions exhibits a three-dimensional shape, i.e. an irregular surface. In an example, this causes many problems in epitaxy regrowth and deposition processes for LEDs.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a bonded substrate, the surface roughness of which is reduced, and a method of manufacturing the same.

In an aspect of the present invention, provided is a bonded substrate that includes a base substrate; an intermediate layer disposed on the base substrate, the intermediate layer having a greater bubble diffusivity than the base substrate; and a thin film layer bonded onto the intermediate layer, the thin film layer having a different chemical composition from the base substrate.

In an exemplary embodiment, the intermediate layer may be made of a material having a lower density than the base substrate.

In an exemplary embodiment, the base substrate may be made of silicon, and the thin film layer may be made of a nitride semiconductor material.

In an exemplary embodiment, the thickness of the thin film layer may range from 0.1 μm to 100 μm.

In an exemplary embodiment, the intermediate layer may be made of SiO₂.

In an aspect of the present invention, provided is a method of manufacturing a bonded substrate that includes the following steps of: preparing a base substrate and a crystalline bulk, the crystalline bulk having a different chemical composition from the base substrate; depositing an intermediate layer on the base substrate, the intermediate layer having a greater bubble diffusivity than the base substrate; bonding the crystalline bulk onto the intermediate layer while allowing bubbles which are created in a bonding interface between the crystalline bulk and the intermediate layer to be discharged through the intermediate layer; and dividing the crystalline bulk to leave a thin film layer on the intermediate layer.

In an exemplary embodiment, the intermediate layer may be made of a material having a lower density than the base substrate.

In an exemplary embodiment, the method may further include the step of, before the step of bonding the crystalline bulk onto the intermediate layer, implanting ions into a predetermined depth from a bonding surface of the crystalline bulk which is to be bonded to the intermediate layer.

In an exemplary embodiment, the step of implanting the ions may use ions of one selected from the group consisting of hydrogen, helium and nitrogen.

In an exemplary embodiment, the step of dividing the crystalline bulk may include heating the crystalline layer so that the crystalline bulk is divided along the ion implantation layer.

In an exemplary embodiment, the step of dividing the crystalline bulk may include cutting the crystalline bulk so that the crystalline bulk is divided along the ion implantation layer.

In an exemplary embodiment, the crystalline bulk may be divided such that the thickness of the thin film layer ranges from 0.1 μm to 100 μm.

In an exemplary embodiment, the base substrate may be made of a silicon substrate, and the crystalline bulk may be made of a nitride semiconductor material. In addition, a sapphire substrate can also be used for the substrate.

In an exemplary embodiment, the intermediate layer may be made of SiO₂. In addition, the intermediate layer made of made of boron nitride (BN).

According to the present invention, the intermediate layer which serves to increase the mobility of voids is disposed between the silicon (Si) substrate and the gallium nitride (GaN) thin film layer. Accordingly, it is possible to reduce the number and area of voids in a bonding interface and increase the bonding area, thereby reducing the surface roughness of the GaN thin film layer.

In addition, according to the invention, it is possible to facilitate crystal regrowth and deposition in the MOCVD epitaxy process, thereby enabling high-quality single crystal growth. This can ultimately improve the characteristics of LED devices.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view depicting a bonded substrate according to an embodiment of the invention;

FIG. 2 is a schematic view depicting the migration of voids in a bonded substrate according to an embodiment of the invention;

FIG. 3A is an optical microscope picture depicting a bonding interface of a bonded substrate according to an embodiment of the invention;

FIG. 3B is an optical microscope picture depicting a bonding interface of a bonded substrate of the related art; and

FIG. 4 to FIG. 7 are process views depicting the sequence of the process of manufacturing a bonded substrate according to an embodiment of the invention.

### DETAILED DESCRIPTION OF THE INVENTION

Reference will now be made in detail to a bonded substrate and a method of manufacturing the same according to the present invention, embodiments of which are illustrated in the accompanying drawings.

In the following description of the present invention, detailed descriptions of known functions and components incorporated herein will be omitted when they may make the subject matter of the present invention unclear.

As shown in FIG. 1, a bonded substrate 100 according to an embodiment of the invention is a semiconductor device substrate which is produced by bonding heterogeneous substrates which have different chemical compositions to each other. The bonded substrate 100 includes a base substrate 110, a thin film layer 120 and an intermediate layer 150.

The base substrate 110 is made of a material having a different chemical composition from the thin film layer 120. In an example, the base substrate 110 may be implemented as a silicon (Si) substrate which exhibits superior electrical conductivity as a vertical LED device substrate. The base substrate 110 serves as a substrate which supports the thin film layer 120 in order to reinforce the strength of the thin film layer 120.

The thin film layer 120 is bonded onto the base substrate 110. Here, the base substrate 110 and the thin film layer 120 are indirectly bonded to each other instead of being directly bonded. This is caused by the intermediate layer 150 which is disposed between the base substrate 110 and the thin film layer 120. The intermediate layer 150 will be described in more detail later. The thin film layer 120 of this embodiment may be made of a nitride semiconductor material. In an example, the thin film layer 120 may be made of a GaN-based nitride semiconductor material which is a group III-V compound. However, in the present invention, the thin film layer 120 is not specially limited to the GaN-based nitride semiconductor material. That is, the thin film layer 120 may be made of other nitride semiconductor materials, such as aluminum nitride (AlN), than the GaN-based nitride semiconductor material. In addition, the thin film layer 120 may be made of any other material selected from candidate materials, including GaAs and InP, than the nitride semiconductor material. It is preferred that the thin film layer 120 have a thickness ranging from 0.1 μm to 100 μm. Here, the thin film layer 120 can be formed separated from the crystalline bulk (120a in FIG. 5) which is grown by a method such as HVPE or HDC so that the thin film layer 120 has the above-mentioned thickness. The method of forming the thin film layer 120 will be described in more detail in the method of manufacturing a bonded substrate which will be described later.

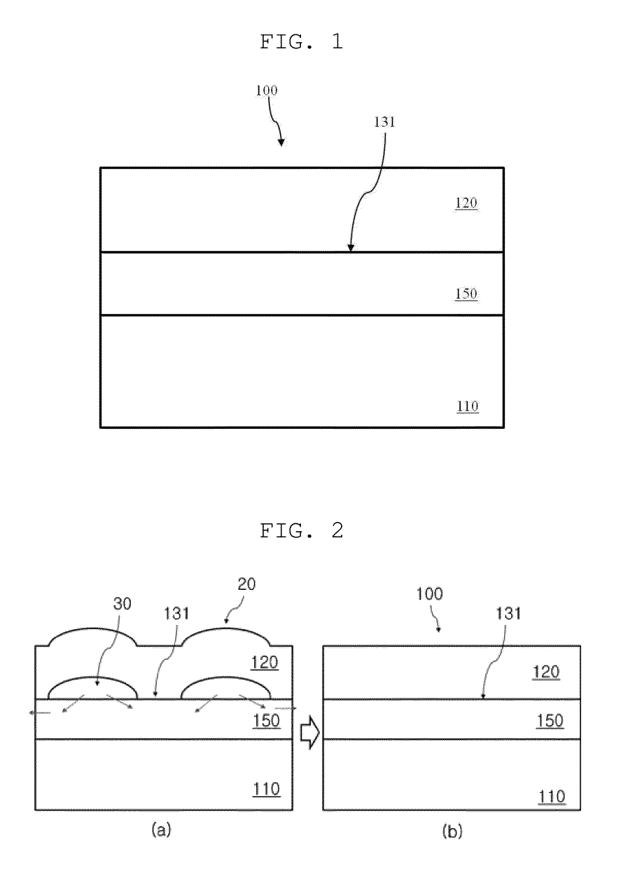

The intermediate layer 150 is disposed between the base substrate 110 and the thin film layer 120. The intermediate layer 150 serves to prevent voids 30 from forming protrusions 20 on the surface of the thin film layer 120 by increasing the mobility of the voids 30 which occur in a bonding interface 131 when the heterogeneous substrates are bonded to each other. Specifically, bubbles which occur in the bonding surfaces of the base substrate 110 and the thin film layer 120 during bonding and heat treatment increase the size through combining with adjacent bubbles without moving out of the interface, thereby forming independent shapes, i.e. the voids 30. In order to prevent this, in the present invention, as shown in FIG. 2, the intermediate layer 150 which increases the mobility of the voids 30 is disposed between the base substrate 110 and the thin film layer 120 in order to move and disperse bubbles which occur so that the bubbles can be actively exhausted out of the bonding interface 131. Accordingly, it is possible to reduce the number and area of the voids 30 and increase the overall bonding area. In addition, when the voids 30 in the bonding interface are reduced owing to the intermediate layer 150, it is possible to reduce surface roughness by decreasing the protrusions 20 on the surface of the thin film layer 120 which are formed by the voids 30. This can facilitate crystal regrowth and deposition in the MOCVD epitaxy process, thereby enabling single crystal growth. This can ultimately improve the characteristics of the LED devices. For this, the bubble diffusivity of the intermediate layer must be greater than that of the base substrate. It is preferred that the intermediate layer be made of a material which has a lower density of than the base substrate. In an example, when the base substrate 110 is implemented as a Si substrate which has a density of 2.33 g/cm³, the intermediate layer 150 can be made of a material which has a lower density than Si in order to easily provide a discharge path for voids. For example, the intermediate layer 150 can be made of SiO₂ which has a density of 2.2 g/cm³.

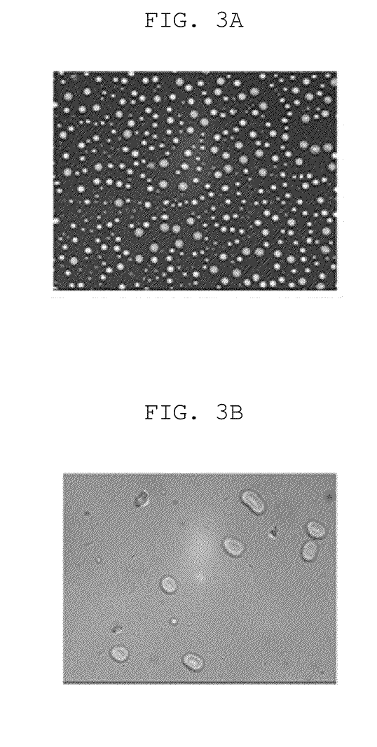

FIG. 3A is an optical microscope picture depicting a bonding interface of a bonded substrate according to an embodiment of the invention, and FIG. 3B is an optical microscope picture depicting a bonding interface of a bonded substrate of the related art. As shown in the pictures in FIG. 3A and FIG. 3B, it can be appreciated with the naked eye that the size and number of voids 30 of a bonded substrate according to an embodiment of the invention (FIG. 3B) are significantly reduced from those of a bonded substrate of the related art (FIG. 3A).

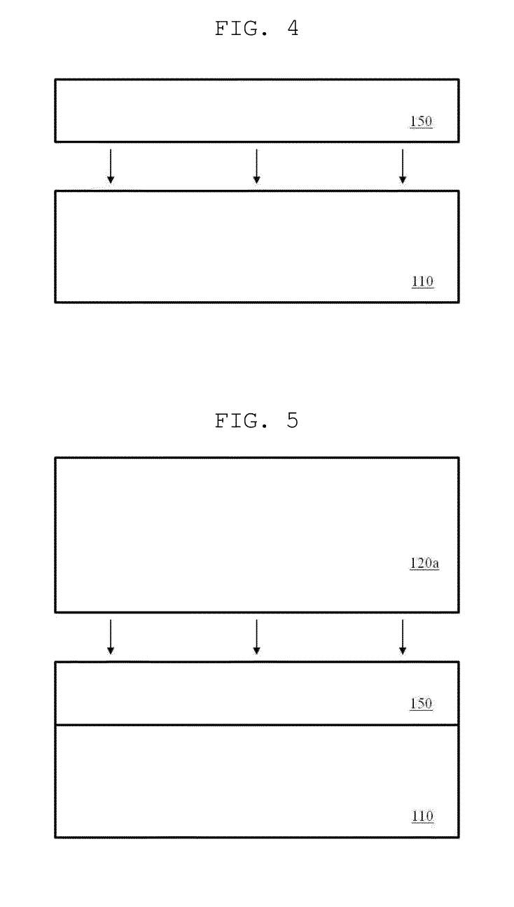

A description will be given below of a method of manufacturing a bonded substrate according to an embodiment of the invention with reference to FIG. 4 to FIG. 7.

The method of manufacturing a bonded substrate of this embodiment includes a preparation step, a deposition step, a bonding step and a dividing step.

First, the preparation step is the step of preparing a base substrate 110 and a crystalline bulk 120a. The crystalline bulk 120a may be made of a nitride semiconductor material. For example, a GaN semiconductor material, a group III-V compound, may be used. In addition, other materials such as AlN, GaAs, InP and the like may be used for the crystalline bulk 120a. When the crystalline bulk 120a is prepared as above, it is preferred that the surface of the crystalline bulk 120a be polished in order to facilitate the subsequent process of bonding the crystalline bulk 120a with the base substrate 110. In an example, when the crystalline bulk 120a is made of GaN, the N surface (N atom surface) of the crystalline bulk 120a may be polished so as to form a mirror surface. This N surface becomes a bonding surface, and the Ga surface (Ga atom surface) is formed on the opposite surface. In addition, in order to increase the strength of bonding, it is possible to control the maximum surface roughness (Rₘₐₓ) by polishing the bonding surface and control the average surface roughness (Rₐ) by etching the bonding surface which has been polished. Here, it is preferred that the maximum surface roughness (Rₘₐₓ) of the bonding surface be controlled so as to be 10 μm or less and the average surface roughness (Rₐ) of the bonding surface be controlled so as to be 1nm or less.

In addition, the base substrate 110 may be made of a material that has a different chemical composition than the crystalline bulk 120a. For example, the base substrate 110 may be implemented as a Si substrate.

In sequence, as shown in FIG. 4, the deposition step is the step of depositing an intermediate layer 150 on one surface of the base substrate 110. The intermediate layer 150 serves to increase the mobility of voids 30 which occur in a bonding interface 131 (see FIG. 2) between the intermediate layer 150 and a thin film layer 120 which is to be formed in the subsequent process, thereby preventing the surface of the thin film layer 120 from swelling owing to the voids 30. The deposition of the intermediate layer 150 may use a heat treatment furnace, chemical vapor deposition, or the like.

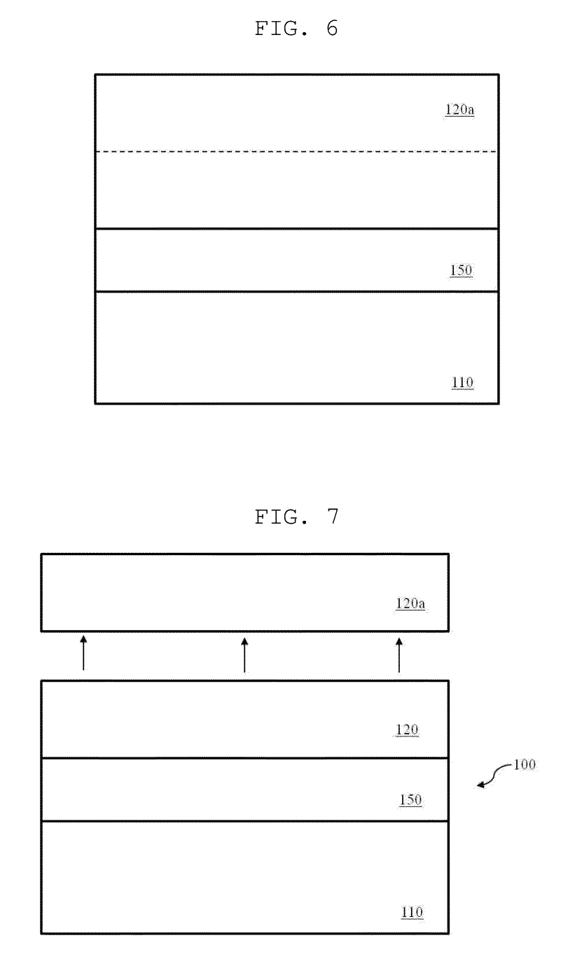

Afterwards, as shown in FIG. 5, the bonding step is the step of bonding the crystalline bulk 120a onto one surface of the intermediate layer 150. As shown in FIG. 6, before the bonding step, an ion implantation layer may be formed by implanting ions to a predetermined depth from the bonding surface of the crystalline bulk 120a which is to be bonded with the intermediate layer 150. Here, it is preferred that ions be implanted to a depth ranging from 0.1 μm to 100 μm from the bonding surface of the crystalline bulk 120a, so that the ion implantation can be formed at this depth. The ion implantation layer will act as an interface later in the dividing step which is intended to form a thin film layer 120 having a thickness ranging from 0.1 μm to 100 μm.

Ions which are implanted in order to form the ion implantation layer may be ions of one selected from among hydrogen, helium and nitrogen. The ion implantation may be carried out using an ion implanter (not shown).

Accordingly, in the bonding step, the crystalline bulk 120a having the ion implantation layer which has been formed as above is bonded onto one surface of the intermediate layer 150. In the bonding step, the crystalline bulk 120a may be bonded to the intermediate layer 150 by applying heat and/or pressure thereon.

In sequence, as shown in FIG. 7, the dividing step is the step of dividing the crystalline bulk 120a along the ion implantation layer which is formed inside the crystalline bulk 120a as an inter. This consequently forms the crystalline thin film layer 120 separated from the crystalline bulk 120a on the stack which includes the base substrate 110 and the intermediate layer 150. The thin film layer dividing step may use a heat treatment method or a cutting method in order to divide the crystalline bulk 120a. The heat treatment method may be useful when the ion implantation layer is formed at a relatively-shallow position inside the crystalline bulk 120a. The heat treatment method is a method that can realize superior precision, be easily carried out, and reliably divide the crystalline bulk 120a. When the base substrate 110, the intermediate layer 150 and the crystalline bulk 120a which are bonded together are heat treated, the ion implantation layer is embrittled, and the crystalline bulk 120a is divided or separated along the implantation layer, leaving only the crystalline thin film layer 120. The temperature at which the heat treatment method is carried out may be adjusted in the range from 300° C. to 600° C. depending on the characteristics of ions that are implanted.

The cutting method may be useful when the ion implantation layer is formed at a relatively deep position inside the crystalline bulk 120a. Like the heat treatment method, the cutting method is a method that can realize superior precision, be easily carried out, and reliably divide the crystalline bulk 120a.

When the crystalline bulk 120a is divided by one of the heat treatment method and the cutting method as described above, the manufacture of a bonded substrate 100 which includes the base substrate 110, the intermediate substrate 150 and the thin film layer 120 is completed.

The remaining crystalline bulk 120a from which a portion is divided as the thin film layer 120 along the ion implantation layer is used for forming a thin film layer 120 of another bonded substrate 100. Accordingly, thin film layers 120 which are applicable to tens to hundreds of bonded substrates 100 can be made using one crystalline bulk 120a.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A bonded substrate comprising:
a base substrate;
an intermediate layer disposed on the base substrate, the intermediate layer having a greater bubble diffusivity than the base substrate; and
a thin film layer bonded onto the intermediate layer, the thin film layer having a different chemical composition from the base substrate.

2. The bonded substrate of claim 1, wherein the intermediate layer comprises a material having a lower density than the base substrate.

3. The bonded substrate of claim 1, wherein the base substrate comprises silicon, and the thin film layer comprises a nitride semiconductor material.

4. The bonded substrate of claim 3, wherein a thickness of the thin film layer ranges from 0.1 μm to 100 μm.

5. The bonded substrate of claim 3, wherein the intermediate layer comprises SiO₂.

6. A method of manufacturing a bonded substrate comprising:
preparing a base substrate and a crystalline bulk, the crystalline bulk having a different chemical composition from the base substrate;
depositing an intermediate layer on the base substrate, the intermediate layer having a greater bubble diffusivity than the base substrate;
bonding the crystalline bulk onto the intermediate layer while allowing bubbles which are created in a bonding interface between the crystalline bulk and the intermediate layer to be discharged through the intermediate layer; and
dividing the crystalline bulk to leave a thin film layer on the intermediate layer.

7. The method of claim 6, wherein the intermediate layer comprises a material having a lower density than the base substrate.

8. The method of claim 7, further comprising, before bonding the crystalline bulk onto the intermediate layer, implanting ions into a predetermined depth from a bonding surface of the crystalline bulk which is to be bonded to the intermediate layer.

9. The method of claim 8, wherein implanting the ions uses ions of one selected from the group consisting of hydrogen, helium and nitrogen.

10. The method of claim 9, wherein dividing the crystalline bulk comprises heating the crystalline layer so that the crystalline bulk is divided along the ion implantation layer.

11. The method of claim 9, wherein dividing the crystalline bulk comprises cutting the crystalline bulk so that the crystalline bulk is divided along the ion implantation layer.

12. The method of claim 6, wherein the crystalline bulk is divided such that a thickness of the thin film layer ranges from 0.1 μm to 100 μm.

13. The method of claim 6, wherein the base substrate comprises a silicon substrate, and the crystalline bulk comprises a nitride semiconductor material.

14. The method of claim 13, wherein the intermediate layer comprises SiO₂.
